(19) United States
(12) Patent Application Publication
(10) Pub. No.: US 2025/0125185 A1
(43) Pub. Date: Apr. 17, 2025

(54) METHOD OF BONDING MULTIPLE COPPER ELEMENTS AND METHOD OF BONDING MULTIPLE DIELECTRIC LAYERS

(71) Applicant: NATIONAL CHENG KUNG UNIVERSITY, Tainan City (TW)

(72) Inventor: Shih-kang LIN, Tainan City (TW)

(21) Appl. No.: 18/910,945

(22) Filed: Oct. 9, 2024

Related U.S. Application Data
(60) Provisional application No. 63/544,190, filed on Oct. 15, 2023.

(51) Int. Cl. H01L 21/762; H01L 21/02; H01L 21/321

(52) U.S. Cl. CPC H01L 21/762; H01L 21/02175; H01L 21/0223; H01L 21/02343; H01L 21/3212

(57) ABSTRACT

A method of bonding multiple copper elements and a method of bonding multiple dielectric layers are disclosed. The method of bonding multiple copper elements comprises steps of: oxidizing a first copper element to form a first copper oxide structure on a surface of the first copper element, and oxidizing a second copper element to form a second copper oxide structure on a surface of the second copper element; immersing the first copper element and the second copper element into a reaction solution containing noble metal ions for a Galvanic reaction, so that the first copper oxide structure is replaced with a first noble metal oxide structure, and the second copper oxide structure is replaced with a second noble metal oxide structure; and bonding the first noble metal oxide structure and the second noble metal oxide structure, so that the first copper component and the second copper component are connected.

### CROSS-REFERENCE TO RELATED APPLICATIONS

This application claims the benefit of U.S. Provisional Application No. 63/544,190, filed on Oct. 15, 2023, which is hereby incorporated by reference in its entirety herein.

### FIELD OF INVENTION

The present disclosure relates to a bonding method, and in particular to a method of bonding multiple copper elements and a method of bonding multiple dielectric layers.

### BACKGROUND OF INVENTION

One of wafer bonding technologies is copper-to-copper hybrid bonding technology, in which metal interconnect layers of two wafers that are to be bonded together are separately manufactured. Each of the metal interconnect layer includes copper and dielectric layer. The dielectric may be silicon oxide or other polymer materials, and copper may be deposited on a surface of the dielectric.

A main process of the copper-to-copper hybrid bonding technology is that: two wafers are aligned face to face after the above-mentioned metal interconnect layers are chemically mechanically polished (CMP) and cleaned. When the copper metal is aligned with the copper metal and the dielectric is aligned with the dielectric in the bonding process of the two wafers, and the two wafers have identical shapes and positions at the bonding interface, copper ions of the two wafers diffuse into the wafer of each other due to mutual diffusion, so as to form a tight and permanent bonding.

However, the copper surfaces become oxidized after ground and polished when exposed to the atmosphere. Therefore, copper oxides, such as copper oxide or cuprous oxide, are formed and thickened during a bonding heating process, hindering diffusion of copper atoms, resulting in a poor bonding efficiency, thereby affecting product performance, yield, and reliability.

In summary, the conventional bonding methods of copper elements need to be improved.

### SUMMARY OF INVENTION

### Technical Problems

A main purpose of the present disclosure is to provide a method of bonding multiple copper elements to solve the above technical problem of reduced bonding efficiency due to natural oxidation of copper surfaces after grinding and polishing.

### Technical Solutions

In order to achieve the foregoing purpose of the present disclosure, the present disclosure provides a method of bonding multiple copper elements, comprising steps of: S11: oxidizing a first copper element to form a first copper oxide structure on a surface of the first copper element, and oxidizing a second copper element to form a second copper oxide structure on a surface of the second copper element; S12: immersing the first copper element comprising the first copper oxide structure and the second copper element comprising the second copper oxide structure into a reaction solution containing a noble metal ion for a Galvanic reaction, so that the first copper oxide structure is replaced with a first noble metal oxide structure, and the second copper oxide structure is replaced with a second noble metal oxide structure; and S13: bonding the first noble metal oxide structure and the second noble metal oxide structure in direct contact at 25 to 500° C. to connect the first copper component with the second copper component.

In one embodiment of the present disclosure, before the step S11, the method of bonding copper element further comprises a step of S10: performing chemical mechanical polishing on the first copper component and the second copper component.

In one embodiment of the present disclosure, the noble metal ion is selected from the group consisting of silver, gold, ruthenium, rhodium, palladium, platinum, and iridium.

In order to achieve the foregoing purpose of the present disclosure, the present disclosure further provides a method of bonding multiple dielectric layers, comprising steps of: S21: oxidizing a first copper layer on a surface of a first dielectric layer to form a first copper oxide structure on a surface of the first copper layer, and oxidizing a second copper layer on a surface of a second dielectric layer to form a second copper oxide structure on a surface of the second copper layer; S22: immersing the first copper layer comprising the first copper oxide structure and the second copper layer comprising the second copper oxide structure into a reaction solution containing a noble metal ion for Galvanic reaction, so that the first copper oxide structure is replaced with a first noble metal oxide structure, and the second copper oxide structure is replaced with a second noble metal oxide structure; and S23: bonding the first noble metal oxide structure and the second noble metal oxide structure in direct contact at 25 to 500° C. to connect the first dielectric layer with the second dielectric layer.

In one embodiment of the present disclosure, before the step S21, the method of bonding multiple dielectric layers further comprises a step of S20: performing chemical mechanical polishing on the first copper layer and the second copper layer.

In one embodiment of the present disclosure, the noble metal ion is selected from the group consisting of silver, gold, ruthenium, rhodium, palladium, platinum, and iridium.

In one embodiment of the present disclosure, the first copper layer is formed on the surface of the first dielectric layer by deposition, and the second copper layer is formed on the surface of the second dielectric layer by deposition.

### Beneficial Effects

Oxygen of noble metal oxides is spontaneously removed by replacing copper oxides with noble metal oxides and using characteristic of noble metal oxides automatically decomposing at high temperatures in the atmosphere, resulting in a bonding structure of copper/noble metal/copper with improved strength and quality, thereby improving the bonding effect of the dielectric layers. In addition, bonding temperatures may be lowered based on the decomposition temperatures of the oxides and the diffusion dynamics to improve the heat accumulation problem in products, reduce the oxides on surfaces, and improve copper atom diffusion.

### DESCRIPTION OF DRAWINGS

In order to more clearly illustrate the above contents of the present disclosure, the following is a detailed description of the preferred embodiments with reference to the accompanying drawings:

FIG. 1 is a flow chart of a method of bonding multiple copper components according to an embodiment of the present disclosure.

FIG. 2 is a flow chart of a method of bonding multiple dielectric layers according to an embodiment of the present disclosure.

FIG. 3 is a schematic structural diagram of a dielectric layer with a deposited copper contact in a method of bonding multiple dielectric layers according to an embodiment of the present disclosure.

FIG. 4 is a schematic structural diagram of a copper oxide generated on a surface of a copper contact in a method of bonding multiple dielectric layers according to an embodiment of the present disclosure.

FIG. 5 is a schematic diagram of a copper contact containing a copper oxide immersed in a silver nitrate solution for a replacement of a silver ion in a method of bonding multiple dielectric layers according to an embodiment of the present disclosure.

FIG. 6 is a schematic diagram of atomic arrangement after a silver replacement is completed in a method of bonding multiple dielectric layers according to an embodiment of the present disclosure.

FIG. 7 is a schematic structural diagram of a copper contact replaced with copper/silver oxide in a method of bonding multiple dielectric layers according to an embodiment of the present disclosure.

FIG. 8 is a schematic structural diagram of automatic decomposition of a silver oxide during a high-temperature bonding process of two dielectric layers in a method of bonding multiple dielectric layers according to an embodiment of the present disclosure.

FIG. 9 is a schematic structural diagram of two dielectric layers which are finally bonded in a method of bonding multiple dielectric layers according to an embodiment of the present disclosure.

FIG. 10 shows an image measured by Field Emission Scanning Electron Microscope (FE-SEM) after a copper was acid-washed with 3.6 wt % hydrochloric acid solution for 3 minutes, wherein a magnification is 15000×.

FIG. 11 is an enlarged view of FIG. 10.

FIG. 12 shows an image measured by FE-SEM after a copper was acid-washed with 3.6 wt % hydrochloric acid solution for 3 minutes and soaked in 1 mM silver nitrate solution for a single-displacement reaction for 10 seconds, wherein a magnification is 10000×.

FIG. 13 is an enlarged view of FIG. 12.

FIG. 14 shows an overall surface signal measured by Energy Dispersive X-Ray (EDX) after the copper was acid-washed with 3.6 wt % hydrochloric acid solution for 3 minutes and soaked in 1 mM silver nitrate solution for the single-displacement reaction for 10 seconds.

FIG. 15 shows a copper element signal measured by EDX after the copper was acid-washed with 3.6 wt % hydrochloric acid solution for 3 minutes and soaked in 1 mM silver nitrate solution for the single-displacement reaction for 10 seconds.

FIG. 16 shows a silver element signal measured by EDX after the copper was acid-washed with 3.6 wt % hydrochloric acid solution for 3 minutes and soaked in 1 mM silver nitrate solution for the single-displacement reaction for 10 seconds.

FIG. 17 shows an image measured by FE-SEM after a copper was acid-washed with 3.6 wt % hydrochloric acid solution for 3 minutes and soaked in 1 mM silver nitrate solution for a single-displacement reaction for 30 seconds, wherein a magnification is 10000×.

FIG. 18 is an enlarged view of FIG. 17.

FIG. 19 shows an overall surface signal measured by EDX after the copper was acid-washed with 3.6 wt % hydrochloric acid solution for 3 minutes and soaked in 1 mM silver nitrate solution for the single-displacement reaction for 30 seconds.

FIG. 20 shows a copper element signal measured by EDX after the copper was acid-washed with 3.6 wt % hydrochloric acid solution for 3 minutes and soaked in 1 mM silver nitrate solution for the single-displacement reaction for 30 seconds.

FIG. 21 shows a silver element signal measured by EDX after the copper was acid-washed with 3.6 wt % hydrochloric acid solution for 3 minutes and soaked in 1 mM silver nitrate solution for the single-displacement reaction for 30 seconds.

FIG. 22 shows an image measured by FE-SEM after a copper was acid-washed with 3.6 wt % hydrochloric acid solution for 3 minutes and soaked in 1 mM silver nitrate solution for a single-displacement reaction for 60 seconds, wherein a magnification is 10000×.

FIG. 23 is an enlarged view of FIG. 22.

FIG. 24 shows an overall surface signal measured by EDX after the copper was acid-washed with 3.6 wt % hydrochloric acid solution for 3 minutes and soaked in 1 mM silver nitrate solution for the single-displacement reaction for 60 seconds.

FIG. 25 shows a copper element signal measured by EDX after the copper was acid-washed with 3.6 wt % hydrochloric acid solution for 3 minutes and soaked in 1 mM silver nitrate solution for the single-displacement reaction for 60 seconds.

FIG. 26 shows a silver element signal measured by EDX after the copper was acid-washed with 3.6 wt % hydrochloric acid solution for 3 minutes and soaked in 1 mM silver nitrate solution for the single-displacement reaction for 60 seconds.

FIG. 27 shows an image measured by FE-SEM after a copper was acid-washed with 3.6 wt % hydrochloric acid solution for 3 minutes and soaked in 1 mM silver nitrate solution for a single-displacement reaction for 120 seconds, wherein a magnification is 10000×.

FIG. 28 is an enlarged view of FIG. 27.

FIG. 29 shows an overall surface signal measured by EDX after the copper was acid-washed with 3.6 wt % hydrochloric acid solution for 3 minutes and soaked in 1 mM silver nitrate solution for the single-displacement reaction for 120 seconds.

FIG. 30 shows a copper element signal measured by EDX after the copper was acid-washed with 3.6 wt % hydrochloric acid solution for 3 minutes and soaked in 1 mM silver nitrate solution for the single-displacement reaction for 120 seconds.

FIG. 31 shows a silver element signal measured by EDX after the copper was acid-washed with 3.6 wt % hydrochloric acid solution for 3 minutes and soaked in 1 mM silver nitrate solution for the single-displacement reaction for 120 seconds.

### DETAILED DESCRIPTION OF PREFERRED EMBODIMENTS

In order to describe the technical solutions of the present disclosure more clearly, numerous specific details are provided in the following specific embodiments. Apparently, the present disclosure can be practiced without certain specific details.

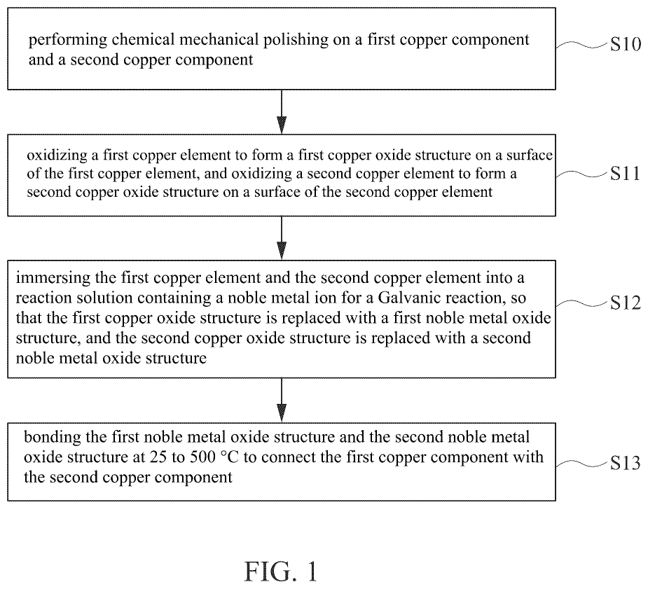

Refer to FIG. 1. A method of bonding multiple copper elements according to an embodiment of the present disclosure comprises the following steps of:
S11 of oxidizing a first copper element to form a first copper oxide structure on a surface of the first copper element, and oxidizing a second copper element to form a second copper oxide structure on a surface of the second copper element.
S12 of immersing the first copper element comprising the first copper oxide structure and the second copper element comprising the second copper oxide structure into a reaction solution containing a noble metal ion for a Galvanic reaction, so that the first copper oxide structure is replaced with a first noble metal oxide structure, and the second copper oxide structure is replaced with a second noble metal oxide structure.
S13 of bonding the first noble metal oxide structure and the second noble metal oxide structure at 25 to 500° C. (e.g., 25, 30, 35, 40, 45, 50, 55, 60, 65, 70, 75, 80, 85, 90, 95, 100, 150, 200, 250, 300, 350, 400, 450, 50° C.) to connect the first copper component with the second copper component are connected.

Optionally, before the step S11, the method of bonding multiple copper elements step further comprises a step of S10 of performing chemical mechanical polishing (CMP) on the first copper element and the second copper element. The first copper element and the second copper element performed chemical mechanical polishing begin to naturally oxidize to produce copper oxides when exposed to the atmosphere.

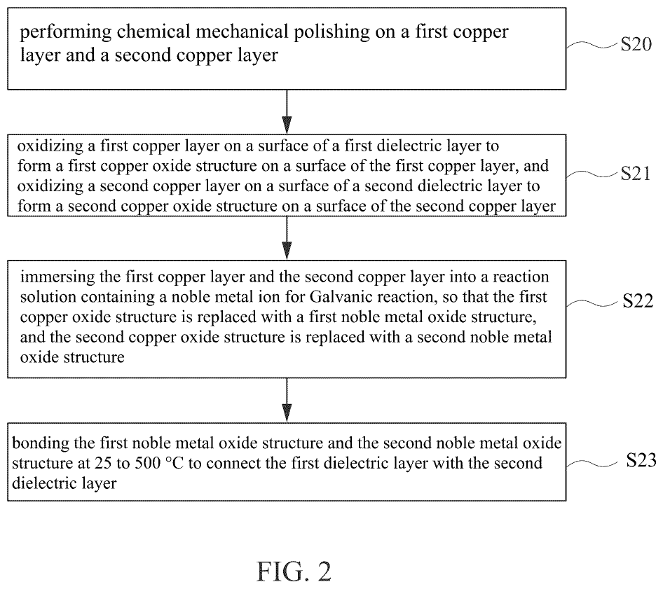

Refer to FIG. 2. A method of bonding multiple dielectric layers according to another embodiment of the present disclosure comprises the following steps of:
S21 of oxidizing a first copper layer on a surface of a first dielectric layer to form a first copper oxide structure on a surface of the first copper layer, and oxidizing a second copper layer on a surface of a second dielectric layer to form a second copper oxide structure on a surface of the second copper layer. Specifically, the first copper layer can be formed on the surface of the first dielectric layer by deposition, and the second copper layer can be formed on the second dielectric layer by deposition. The deposition may be physical deposition or chemical deposition.
S22 of immersing the first copper layer comprising the first copper oxide structure and the second copper layer comprising the second copper oxide structure into a reaction solution containing a noble metal ion for Galvanic reaction. Thus, the first copper oxide structure is replaced with a first noble metal oxide structure, and the second copper oxide structure is replaced with a second noble metal oxide structure. Specifically, the noble metal ion is selected from the group consisting of silver, gold, ruthenium, rhodium, palladium, platinum, and iridium.
S23 of bonding the first noble metal oxide structure and the second noble metal oxide structure in direct contact at 25 to 500° C. (e.g., 25, 30, 35, 40, 45, 50, 55, 60, 65, 70, 75, 80, 85, 90, 95, 100, 150, 200, 250, 300, 350, 400, 450, 500° C.) to connect the first dielectric layer with the second dielectric layer.

Optionally, before the step S21, the method of bonding multiple dielectric layers further comprises a step of S20 of performing chemical mechanical polishing on the first copper layer and the second copper layer. The first copper layer and the second copper layer performed chemical mechanical polishing begin to naturally oxidize to produce copper oxides when exposed to the atmosphere.

It is expected that during the life of a patent maturing from this application many related technologies for methods of bonding multiple copper components and methods of bonding dielectric layers will be developed and the scope of this application is intended to include all such new technologies a priori.

Throughout the present application, various embodiments of the present disclosure may be presented in a range format. It should be understood that the description in range format is merely for convenience and brevity and should not be construed as an inflexible limitation on the scope of the present disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

As used herein the terms “process” and “method” refer to manners, means, techniques and procedures for accomplishing a given task including, but not limited to, those manners, means, techniques and procedures either known to, or readily developed from known manners, means, techniques and procedures by practitioners of the chemical, material, mechanical, computing, and digital fields.

Reference is now made to the following examples, which together with the above descriptions, illustrate the invention in a non-limiting fashion.

### EXAMPLE

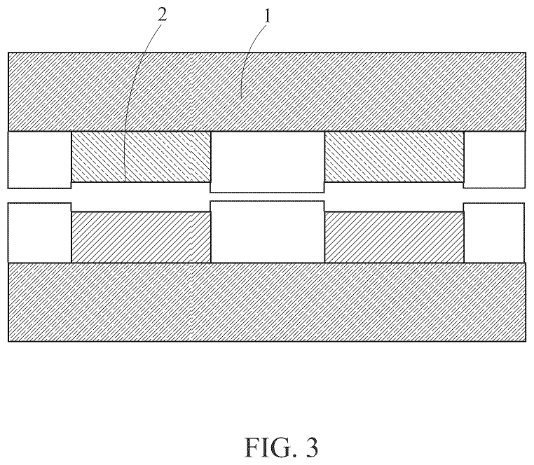

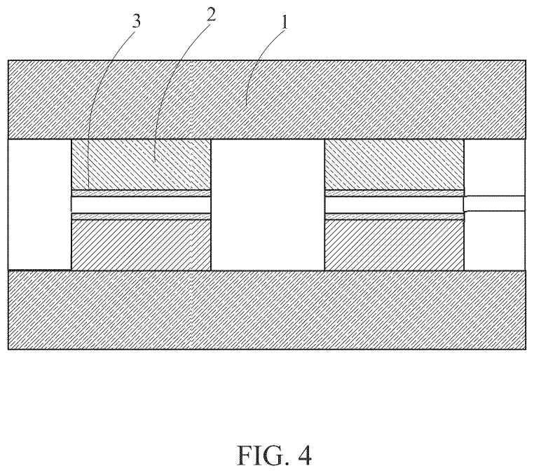

Refer to FIG. 3. First, a copper contact 2 (i.e., the first copper layer or the second copper layer of the present disclosure) was deposited on a dielectric layer 1 (i.e., the first dielectric layer or the second dielectric layer of the present disclosure), and chemical mechanical polishing was performed on a surface. Refer to FIG. 4. After polishing, when the copper contact 2 was exposed to the atmosphere, a copper oxide 3, such as copper oxide/cuprous oxide (CuO/Cu₂O), was generated on the surface.

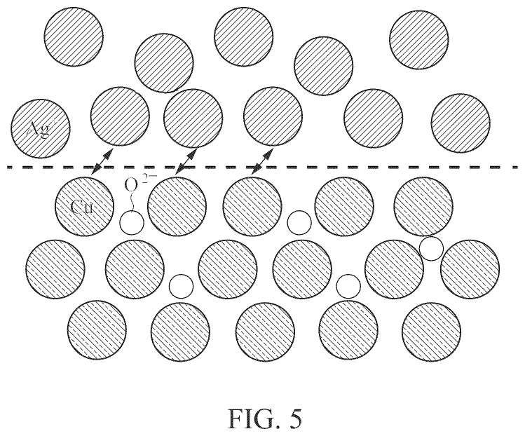

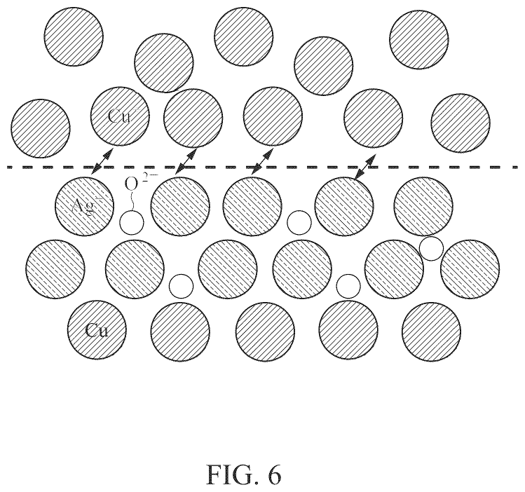

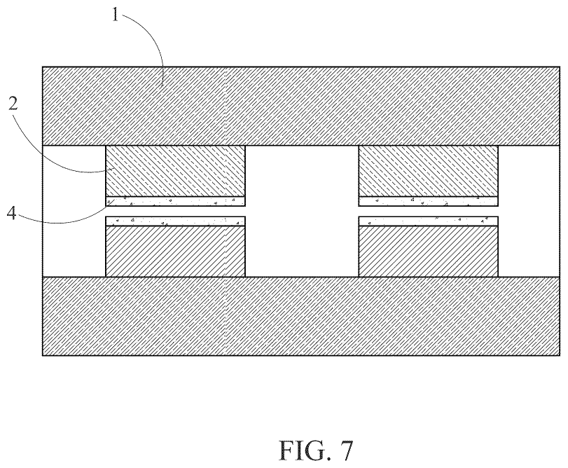

Then, the copper contact 2 was immersed in the AgNO₃ solution to perform Galvanic reaction for surface metal replacement. FIG. 5 and FIG. 6 show that copper ions in the cuprous oxide were spontaneously replaced with silver ions. Silver oxide (Ag₂O) 4 replaced an original copper oxide to form a structure of copper/silver oxide, as shown in FIG. 7.

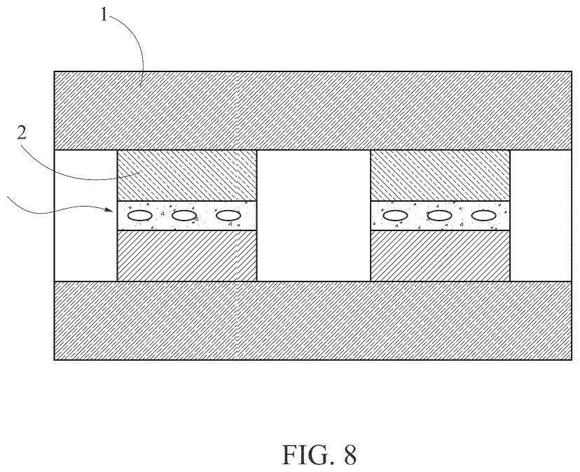

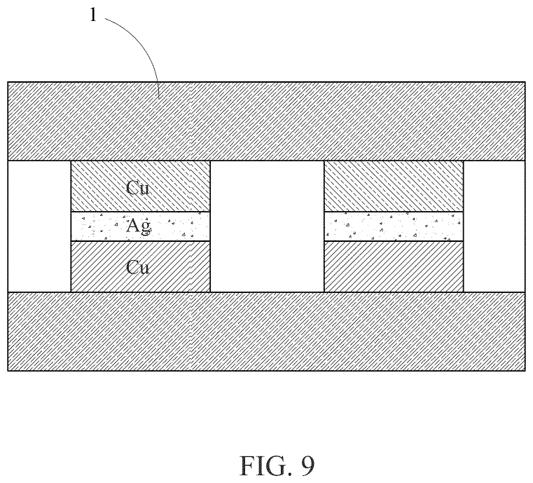

Finally, two dielectric layers respectively containing the structure of copper/silver oxide were connected symmetrically with the structure of copper/silver oxide at 150° C., where a connection method of copper/silver oxide to silver oxide/copper bonding was used, so that he two dielectric layers were connected. A characteristics of noble metal oxides automatically decomposing at high temperatures in the atmosphere is used. For example, Ag₂O and Au₃O₄ decompose at 150° C. and a room temperature respectively. As indicated by an arrow in FIG. 8, Ag₂O decomposed to release oxygen and silver to spontaneously remove oxygen on the surface. It is worth mentioning that bonding temperatures may be lowered based on the decomposition temperatures of the oxides and the diffusion dynamics, thereby improving the heat accumulation problem in products, reducing the oxides on surfaces, and further improving copper atom diffusion, resulting in optimal bonding interfaces with improved strength and quality, such as a copper/silver/copper structure as shown in FIG. 9.

### Replacement Results

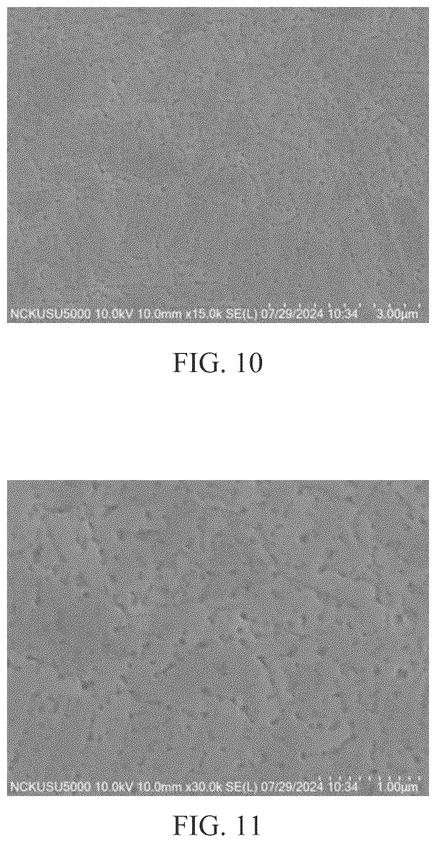

FIG. 10 shows an image measured by Field Emission Scanning Electron Microscope (FE-SEM) after a copper was acid-washed with 3.6 wt % hydrochloric acid solution for 3 minutes, wherein a magnification is 15000×. A result shows that a pure copper surface with removed oxides is obtained. FIG. 11 is an enlarged view of FIG. 10.

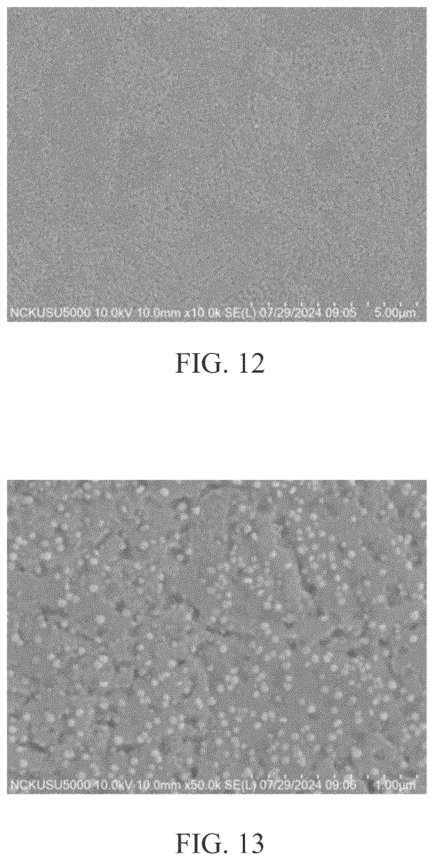

FIG. 12 shows an image measured by FE-SEM after a copper was acid-washed with 3.6 wt % hydrochloric acid solution for 3 minutes and soaked in 1 mM silver nitrate solution for a single-displacement reaction for 10 seconds, wherein a magnification is 10000×. A result shows that silver atoms are attached to a copper surface after the single-displacement reaction. FIG. 13 is an enlarged view of FIG. 12.

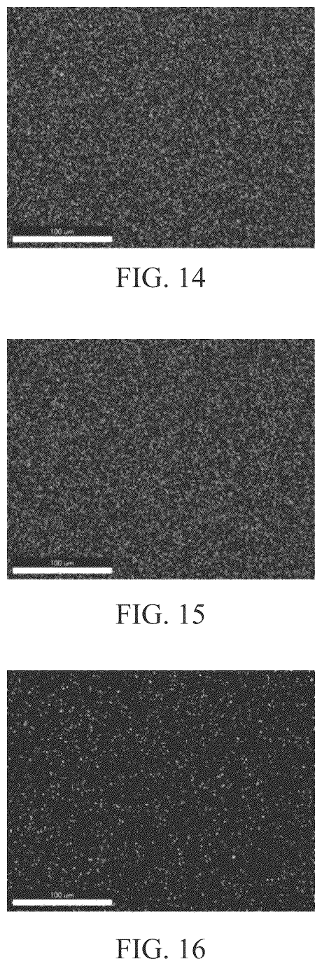

FIG. 14 shows an overall surface signal measured by Energy Dispersive X-Ray (EDX) after the copper was acid-washed with 3.6 wt % hydrochloric acid solution for 3 minutes and soaked in 1 mM silver nitrate solution for the single-displacement reaction for 10 seconds. A result shows that since silver particles are small, the overall surface signal is a copper signal by mapping analysis of the EDX. FIG. 15 shows a copper element signal measured by EDX after the copper was acid-washed with 3.6 wt % hydrochloric acid solution for 3 minutes and soaked in 1 mM silver nitrate solution for the single-displacement reaction for 10 seconds. A result shows that there is a uniform layer of copper underneath the silver atoms. FIG. 16 shows a silver element signal measured by EDX after the copper was acid-washed with 3.6 wt % hydrochloric acid solution for 3 minutes and soaked in 1 mM silver nitrate solution for the single-displacement reaction for 10 seconds. A result shows that silver atoms are evenly distributed on the copper surface.

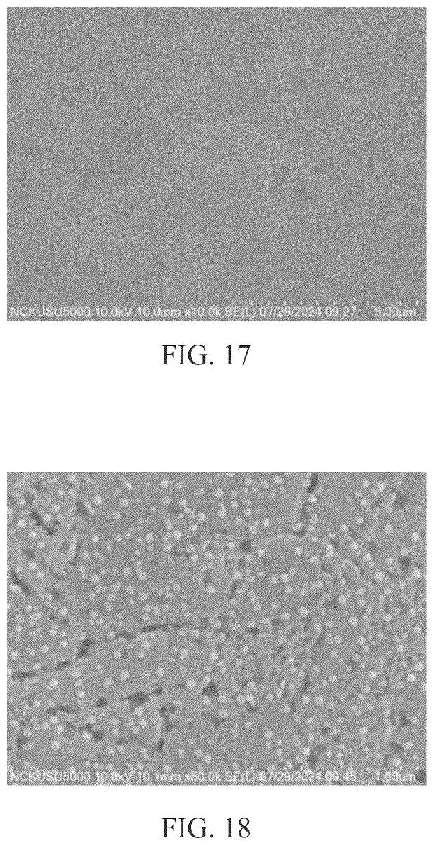

FIG. 17 shows an image measured by FE-SEM after a copper was acid-washed with 3.6 wt % hydrochloric acid solution for 3 minutes and soaked in 1 mM silver nitrate solution for a single-displacement reaction for 30 seconds. A result shows that as time for the single-displacement reaction increases, silver atoms are more densely attached to a copper surface. FIG. 18 is an enlarged view of FIG. 17.

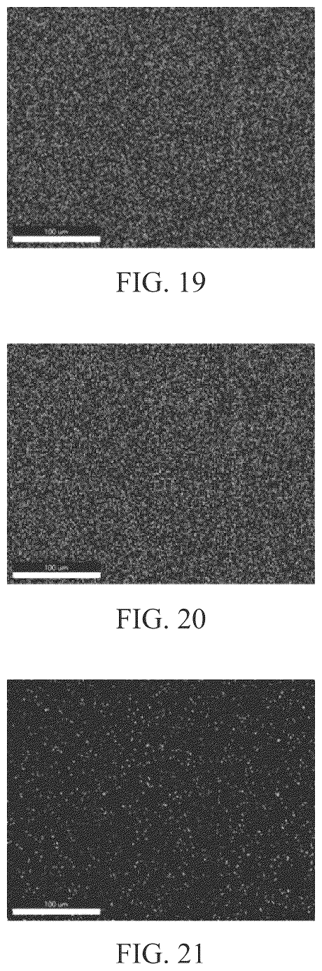

FIG. 19 shows an overall surface signal measured by EDX after the copper was acid-washed with 3.6 wt % hydrochloric acid solution for 3 minutes and soaked in 1 mM silver nitrate solution for the single-displacement reaction for 30 seconds. A result shows that since silver particles are small, the overall surface signal is a copper signal by mapping analysis of the EDX. FIG. 20 shows a copper element signal measured by EDX after the copper was acid-washed with 3.6 wt % hydrochloric acid solution for 3 minutes and soaked in 1 mM silver nitrate solution for the single-displacement reaction for 30 seconds. A result shows that there is a uniform layer of copper underneath the silver atoms. FIG. 21 shows a silver element signal measured by EDX after the copper was acid-washed with 3.6 wt % hydrochloric acid solution for 3 minutes and soaked in 1 mM silver nitrate solution for the single-displacement reaction for 30 seconds. A result shows that compared to the single-displacement reaction for 10 seconds, the overall silver atom signal is more dense, meaning that silver atoms are more densely attached to the copper surface.

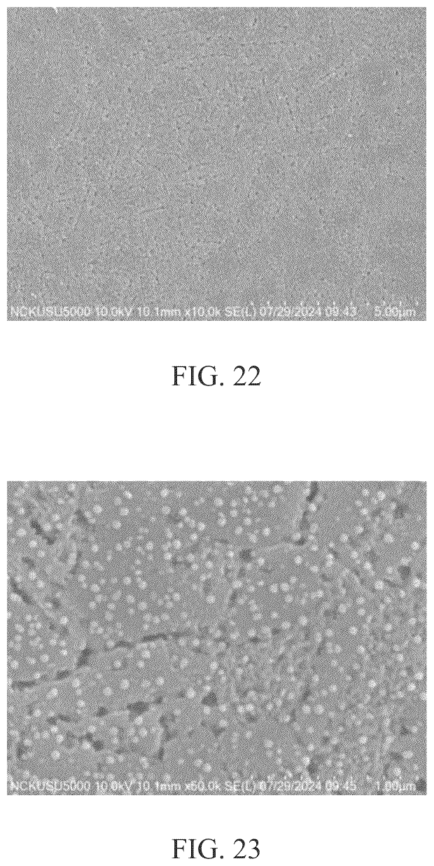

FIG. 22 shows an image measured by FE-SEM after a copper was acid-washed with 3.6 wt % hydrochloric acid solution for 3 minutes and soaked in 1 mM silver nitrate solution for a single-displacement reaction for 60 seconds. A result shows that as time for the single-displacement reaction increases, silver atoms are more densely attached to a copper surface. FIG. 23 is an enlarged view of FIG. 22.

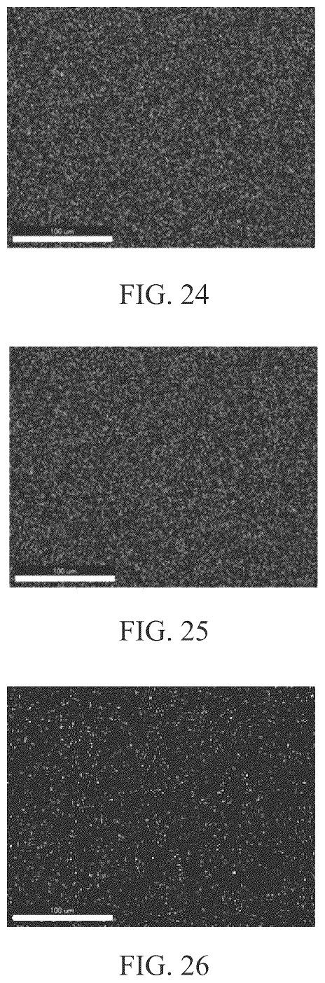

FIG. 24 shows an overall surface signal measured by EDX after the copper was acid-washed with 3.6 wt % hydrochloric acid solution for 3 minutes and soaked in 1 mM silver nitrate solution for the single-displacement reaction for 60 seconds. A result shows that since silver particles are small, the overall surface signal is a copper signal by mapping analysis of the EDX. FIG. 25 shows a copper element signal measured by EDX after the copper was acid-washed with 3.6 wt % hydrochloric acid solution for 3 minutes and soaked in 1 mM silver nitrate solution for the single-displacement reaction for 60 seconds. A result shows that there is a uniform layer of copper underneath the silver atoms. FIG. 26 shows a silver element signal measured by EDX after the copper was acid-washed with 3.6 wt % hydrochloric acid solution for 3 minutes and soaked in 1 mM silver nitrate solution for the single-displacement reaction for 60 seconds. A result shows that compared to the single-displacement reaction for 30 seconds, the overall silver atom signal is more dense, meaning that silver atoms are more densely attached to the copper surface.

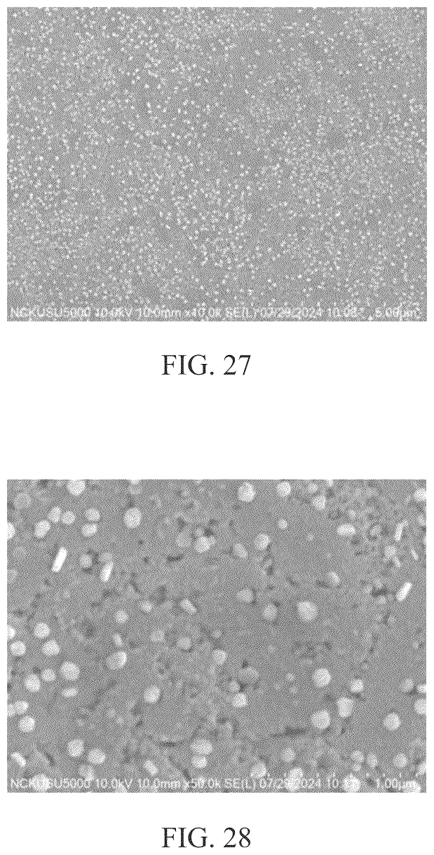

FIG. 27 shows an image measured by FE-SEM after a copper was acid-washed with 3.6 wt % hydrochloric acid solution for 3 minutes and soaked in 1 mM silver nitrate solution for a single-displacement reaction for 120 seconds. A result shows that as time for the single-displacement reaction increases, silver atoms are more densely attached to a copper surface. 120 seconds is the most obvious among all times for the single-displacement reactions. FIG. 28 is an enlarged view of FIG. 27.

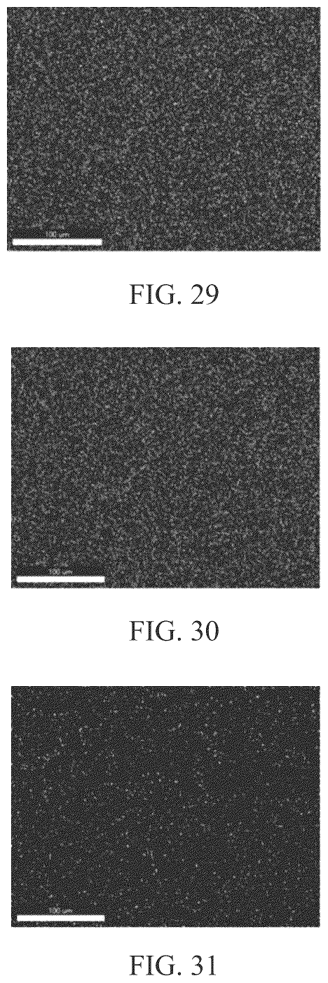

FIG. 29 shows an overall surface signal measured by EDX after the copper was acid-washed with 3.6 wt % hydrochloric acid solution for 3 minutes and soaked in 1 mM silver nitrate solution for the single-displacement reaction for 120 seconds. A result shows that since silver particles are small, the overall surface signal is a copper signal by mapping analysis of the EDX. However, as time for the single-displacement reaction increases, some silver particles with larger size appear in the figure. FIG. 30 shows a copper element signal measured by EDX after the copper was acid-washed with 3.6 wt % hydrochloric acid solution for 3 minutes and soaked in 1 mM silver nitrate solution for the single-displacement reaction for 120 seconds. A result shows that there is a uniform layer of copper underneath the silver atoms. FIG. 31 shows a silver element signal measured by EDX after the copper was acid-washed with 3.6 wt % hydrochloric acid solution for 3 minutes and soaked in 1 mM silver nitrate solution for the single-displacement reaction for 120 seconds. A result shows that compared to the single-displacement reaction for 60 seconds, the overall silver atom signal is stronger, and silver atoms are more densely distributed on the copper surface.

While the preferred embodiments of the present disclosure have been described above, it will be recognized and understood that various changes and modifications can be made, and the appended claims are intended to cover all such changes and modifications which may fall within the spirit and scope of the present disclosure.

What is claimed is:

1. A method of bonding multiple copper elements, comprising steps of:
S11: oxidizing a first copper element to form a first copper oxide structure on a surface of the first copper element, and oxidizing a second copper element to form a second copper oxide structure on a surface of the second copper element;
S12: immersing the first copper element comprising the first copper oxide structure and the second copper element comprising the second copper oxide structure into a reaction solution containing a noble metal ion for a Galvanic reaction, so that the first copper oxide structure is replaced with a first noble metal oxide structure, and the second copper oxide structure is replaced with a second noble metal oxide structure; and
S13: bonding the first noble metal oxide structure and the second noble metal oxide structure in direct contact at 25 to 500° C. to connect the first copper component with the second copper component.

2. The method of bonding multiple copper elements as claimed in claim 1, before the step S11, further comprising a step S10 of performing chemical mechanical polishing on the first copper component and the second copper component.

3. The method of bonding multiple copper elements as claimed in claim 1, wherein the noble metal ion is selected from the group consisting of silver, gold, ruthenium, rhodium, palladium, platinum, and iridium.

4. A method of bonding multiple dielectric layers, comprising steps of:
S21: oxidizing a first copper layer on a surface of a first dielectric layer to form a first copper oxide structure on a surface of the first copper layer, and oxidizing a second copper layer on a surface of a second dielectric layer to form a second copper oxide structure on a surface of the second copper layer;
S22: immersing the first copper layer comprising the first copper oxide structure and the second copper layer comprising the second copper oxide structure into a reaction solution containing a noble metal ion for Galvanic reaction, so that the first copper oxide structure is replaced with a first noble metal oxide structure, and the second copper oxide structure is replaced with a second noble metal oxide structure; and
S23: bonding the first noble metal oxide structure and the second noble metal oxide structure in direct contact at 25 to 500° C. to connect the first dielectric layer with the second dielectric layer.

5. The method of bonding multiple dielectric layers as claimed in claim 4, before the step S21, further comprising a step S20 of performing chemical mechanical polishing on the first copper layer and the second copper layer.

6. The method of bonding multiple dielectric layers as claimed in claim 4, wherein the noble metal ion is selected from the group consisting of silver, gold, ruthenium, rhodium, palladium, platinum, and iridium.

7. The method of bonding multiple dielectric layers as claimed in claim 4, wherein the first copper layer is formed on the surface of the first dielectric layer by deposition, and the second copper layer is formed on the surface of the second dielectric layer by deposition.
